(19) United States
(12) Patent Application Publication
(10) Pub. No.: US 2026/0052927 A1
(43) Pub. Date: Feb. 19, 2026

(54) SEMICONDUCTOR CHIP, SEMICONDUCTOR PACKAGE INCLUDING SEMICONDUCTOR CHIP AND METHOD FOR MANUFACTURING THE SAME

(71) Applicant: Samsung Electronics Co., Ltd., Suwon-si (KR)

(72) Inventors: Hyunhee LEE, Suwon-si (KR); Hyeongmun KANG, Suwon-si (KR); Jungmin KO, Suwon-si (KR); Taehyeong KIM, Suwon-si (KR)

(73) Assignee: Samsung Electronics Co., Ltd., Suwon-si (KR)

(21) Appl. No.: 19/061,515

(22) Filed: Feb. 24, 2025

(30) Foreign Application Priority Data
Aug. 16, 2024 (KR) 10-2024-0109703

(51) Int. Cl. H01L 21/78; H01L 21/56; H01L 21/762; H01L 23/00; H01L 23/31; H01L 23/58

(52) U.S. Cl. CPC H01L 21/78; H01L 21/563; H01L 21/565; H01L 21/76224; H01L 23/3178; H01L 23/562; H01L 23/585

(57) ABSTRACT

A semiconductor package according to some example embodiments may include a chip base including a main chip region and an edge region around the main chip region, a device layer on the chip base, a wiring layer on the device layer, an upper insulating stack on the wiring layer, and a trench on the edge region, the trench recessed from the upper insulating stack to the device layer, and an inner surface of the trench exposed to an outside of the semiconductor chip.

### CROSS-REFERENCE TO RELATED APPLICATION

This application claims priority to and the benefit of Korean Patent Application No. 10-2024-0109703 filed in the Korean Intellectual Property Office on Aug. 16, 2024, the entire contents of which are incorporated herein by reference.

### BACKGROUND

Some example embodiments relate to a semiconductor chip, a semiconductor package including the semiconductor chip, and a method for manufacturing the same.

A semiconductor chip may include a chip region including integrated circuits, and an edge region around the chip region. When physical stress is applied to the side surface of the edge region of the semiconductor chip, cracks may be generated in the edge region of the semiconductor chip. Cracks generated in the edge region may propagate from the edge region to the chip region, and cracks that propagate to the chip region of the semiconductor chip may affect integrated circuits or wiring lines, thereby potentially making the semiconductor chip malfunction and/or reducing the reliability of the semiconductor chip.

In order to reduce and/or prevent malfunctions and/or reliability failures, a semiconductor chip has been proposed which may include a trench formed in an edge region and filled with an interlayer dielectric material, which is a gap filling material, such that cracks generated in the edge region of the semiconductor chip may be reduced and/or prevented from propagating to a chip region. The trench structure may be filled with the gap filling material, and may propagate cracks generated in the edge region in a direction different from the direction toward the chip region. However, since the interlayer dielectric material has a hard property, and the gap filling material having the hard property is fragile, despite the presence of the trench structure, it is not uncommon for cracks to propagate to the chip region while damaging the gap filling material in the trench. Furthermore, as semiconductor chips have become thinner due to the generational transitions in semiconductor products, the frequency of occurrence of cracks in the edge regions of semiconductor chips may be increased, which may result in an increase in the risk of cracks in the semiconductor chips.

### SUMMARY

Some example embodiments of the present disclosure provide a semiconductor chip including a trench consisting of an empty space exposed to an outside of the semiconductor chip.

In the course of forming a semiconductor package, the empty space in a trench in the semiconductor chip may be filled with an underfill member having a low modulus.

In the course of forming the semiconductor package, the trench in the semiconductor chip may include a void that is defined by the inner surface of the trench and an underfill member positioned on the opening of the trench, inside the trench.

A semiconductor chip according to some example embodiments may include a chip base including a main chip region and an edge region around the main chip region, a device layer on the chip base, a wiring layer on the device layer, an upper insulating stack on the wiring layer, and a trench on the edge region, the trench recessed from the upper insulating stack to the device layer, and an inner surface of the trench exposed to an outside of the semiconductor chip.

A semiconductor package according to some example embodiments may include a base structure, an underfill member on the base structure, and a semiconductor chip on the underfill member, the semiconductor chip including a chip base including a main chip region and an edge region around the main chip region, a device layer on the chip base, a wiring layer on the device layer, an upper insulating stack on the wiring layer, and a first trench on the edge region, the first trench recessed from the upper insulating stack to the device layer, and an inner surface of the first trench is exposed to an outside of the semiconductor chip. The first trench is fully filled with the underfill member, or the first trench includes a void defined by the inner surface of the first trench and the underfill member.

A semiconductor package according to some example embodiments may include a base die, one or more underfill members and a plurality of semiconductor chips alternately stacked on the base die, and a molding material covering the one or more underfill members and the plurality of semiconductor chips on the base die. Each of the plurality of semiconductor chips includes a chip base including a main chip region and an edge region around the main chip region, a device layer on the chip base, a wiring layer on the device layer, an upper insulating stack on the wiring layer, and a first trench on the edge region, the first trench recessed from the upper insulating stack to the device layer, an inner surface of the first trench exposed to an outside of each of the plurality of semiconductor chips, and the first trench filled with an underfill member, or the first trench includes a void defined by the inner surface of the first trench and an underfill member adjacent to the first trench.

By including a trench filled with an underfill member having a low modulus and/or by including a trench with a void, it is possible to reduce and/or prevent the propagation of cracks generated in the edge region of a semiconductor chip.

In consideration of the characteristics of semiconductor chips according to a generational transition in semiconductor products, optimal trench structures capable of limiting and/or preventing propagation of cracks may be designed. For example, inside a semiconductor chip, a plurality of trenches filled with underfill members having a low modulus or a plurality of trenches with voids may be disposed, or trenches filled with underfill members and trenches with voids may be alternately disposed.

### BRIEF DESCRIPTION OF THE DRAWINGS

FIG. 1 is a view illustrating a semiconductor wafer according to some example embodiments.

FIG. 2 is a plan view illustrating a cross section of a semiconductor chip according to some example embodiments taken along line a horizontal direction.

FIG. 3 is a plan view illustrating a cross section of the semiconductor chip according to some example embodiments taken along line a horizontal direction.

FIG. 4 is a cross-sectional view illustrating the semiconductor chip according to some example embodiments.

FIG. 5 is an enlarged cross-sectional view illustrating a region C of FIG. 4.

FIG. 6 is a cross-sectional view illustrating a semiconductor package according to some example embodiments.

FIG. 7 is a cross-sectional view illustrating a trench according to some example embodiments.

FIG. 8 is a cross-sectional view illustrating a trench according to some example embodiments.

FIG. 9 is a cross-sectional view illustrating a trench according to some example embodiments.

FIG. 10 is a cross-sectional view illustrating a semiconductor package according to some example embodiments.

FIG. 11 is a cross-sectional view illustrating a semiconductor package according to some example embodiments.

FIG. 12 is a cross-sectional view illustrating a semiconductor package according to some example embodiments.

FIG. 13 is a cross-sectional view illustrating a semiconductor package according to some example embodiments.

FIGS. 14 and 15 are cross-sectional views illustrating a method of forming the semiconductor chip of FIG. 4 from the semiconductor wafer of FIG. 1.

FIGS. 16 to 19 are cross-sectional views illustrating a method of manufacturing the semiconductor package according to some example embodiments as represented by FIG. 6.

FIGS. 20 to 22 are cross-sectional views illustrating a method of manufacturing the semiconductor package according to some example embodiments as represented by FIG. 10.

FIGS. 23 to 25 are cross-sectional views illustrating a method of manufacturing the semiconductor package according to some example embodiments as represented by FIG. 11.

FIGS. 26 and 27 are cross-sectional views illustrating a method of manufacturing the semiconductor package according to some example embodiments as represented by FIG. 12.

### DETAILED DESCRIPTION

In the following detailed description, some example embodiments of the present disclosure have been shown and described, simply by way of illustration. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, or “in a planar view”, it means when a target part is viewed from above, and when it is referred to as “on a cross-section”, it means when the cross-section obtained by cutting a target part vertically is viewed from the side.

Hereinafter, a semiconductor chip 100 according to some example embodiments, semiconductor packages 200A, 200B, 300A, 300B, and 400, and manufacturing methods of the semiconductor packages 200A, 200B, 300A, and 300B will be described with reference to the drawings.

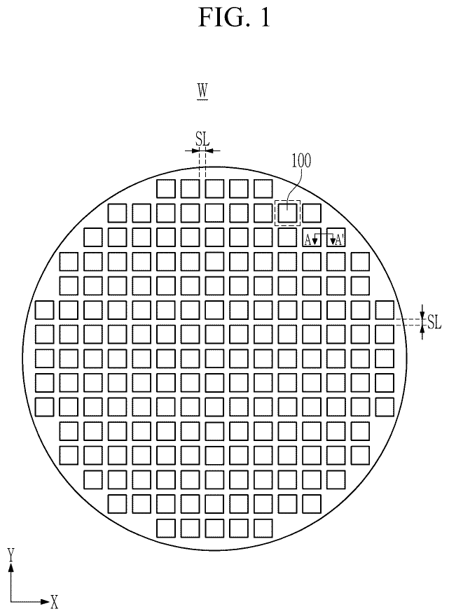

FIG. 1 is a view illustrating a semiconductor wafer W according to some example embodiments.

Referring to FIG. 1, a semiconductor wafer W may include main chip regions (chip regions) MR and a scribe lane SL. The main chip regions MR and the scribe lane SL may be defined by dividing the plane of the semiconductor wafer W.

Each of the main chip regions MR may have a rectangular shape on a plane. The shape of a main chip region MR may be defined by four side surfaces each of which extends in a first horizontal direction X or a second horizontal direction Y. In this case, the first horizontal direction X and the second horizontal direction Y may intersect or be orthogonal to each other. The upper surface of a main chip region MR may be defined in a vertical direction Z. In this case, the vertical direction Z may intersect or be orthogonal to both of the first horizontal direction X and the second horizontal direction Y. In each of the main chip regions MR, active devices or passive devices may be formed.

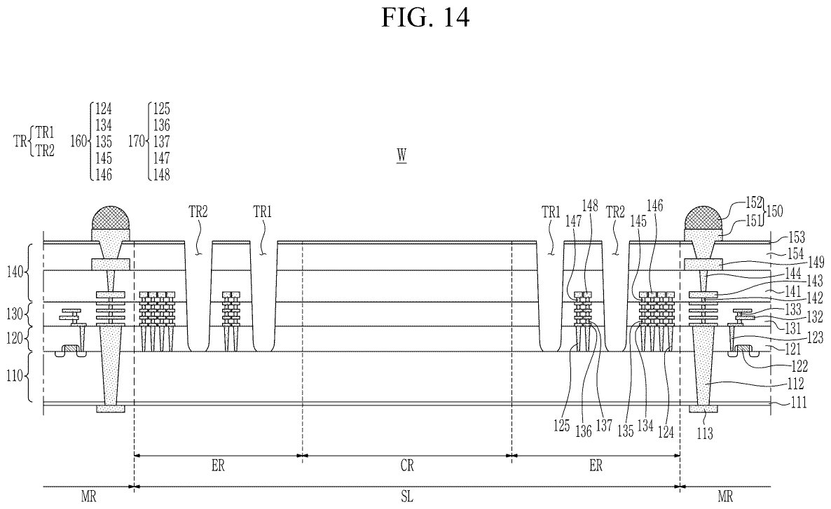

The scribe lane SL may be defined as a region between the main chip regions MR. Referring to FIG. 14, the scribe lane SL may include a cutting region CR and an edge region ER. The cutting region CR and the edge region ER may be defined by dividing the plane of the scribe lane SL.

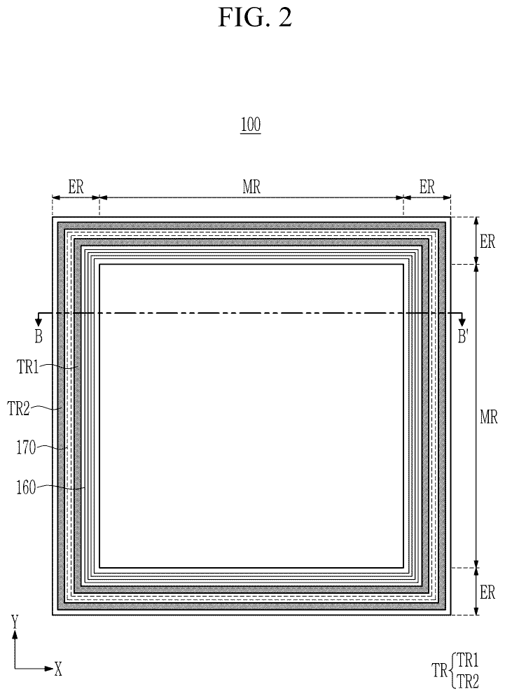

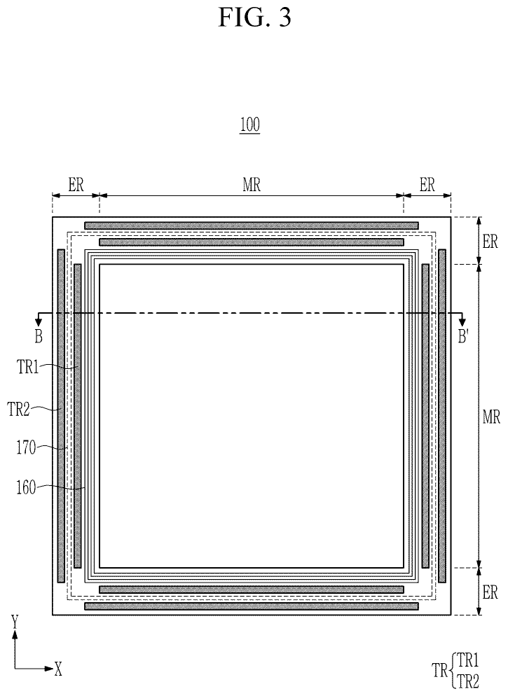

FIG. 2 is a plan view illustrating a cross section of the semiconductor chip 100, according to some example embodiments, in a horizontal direction. FIG. 3 is a plan view illustrating a cross section of the semiconductor chip 100, according to some example embodiments, in a horizontal direction.

Referring to FIGS. 2 and 3, the semiconductor wafer W may be divided into the individual semiconductor chip 100 by performing a singulation process along the scribe lane SL. The semiconductor chip 100 may include a main chip region MR and the edge region ER of the scribe lane SL.

The singulation process may be performed by a laser, sawing, etc., however, example embodiments are not limited thereto, and in the course of performing the singulation process, physical stress may be applied to the side surfaces of the semiconductor chip, whereby cracks may be generated in the edge region. Further, the side surfaces of the semiconductor chip after being cut have the property of being vulnerable to moisture. Moisture penetrating into the side surfaces of the semiconductor chip may weaken the bonding strength between the interfaces of material films, causing cracks to be generated in the edge region.

The cracks generated in the edge region of the semiconductor chip as described above may extend into the semiconductor chip and propagate to the main chip region. The cracks propagating to the main chip region of the semiconductor chip may affect integrated circuits or wiring lines and cause semiconductor chip malfunctions and/or reduce the reliability of the semiconductor chip.

The semiconductor chip 100 may include a guide ring structure 160, dam structures 170, and a trench TR in the edge region ER. The guide ring structure 160, the dam structures 170, and the trench TR may serve as barriers for limiting and/or preventing cracks generated in the edge region from propagating to the main chip region.

The guide ring structure 160 may extend so as to conform to the side surfaces of the main chip region MR. In some example embodiments, on a plane, the guide ring structure 160 may have a rectangular frame shape continuously extending along the perimeter of the main chip region MR. The number of guide ring structures 160 may be two or more. Each of the plurality of guide ring structures 160 may extend so as to conform to a neighboring guide ring structure 160. The plurality of guide ring structures 160 may be disposed so as to be spaced apart from each other by a desired (and/or alternatively predetermined) distance in the first horizontal direction X or the second horizontal direction Y. The plurality of guide ring structures 160 may be disposed side by side with each other.

The dam structures 170 may extend so as to conform to the side surfaces of the main chip region MR. The dam structures 170 may extend in a line along the side surfaces of the main chip region MR. In some example embodiments, on a plane, the dam structures 170 that extend in a line may have a rectangular frame shape that continuously extends along the perimeter of the main chip region MR. Each of the dam structures 170 that extend in a line may be disposed so as to be spaced apart from a neighboring dam structure 170 of the dam structures 170, which extend in a line, by a desired (and/or alternatively predetermined) distance. The dam structures 170 that extend in a line may be defined as one set, and the number of sets of dam structures 170 may be two or more. Each of the plurality of sets of dam structures 170 may extend so as to conform to neighboring dam structures 170. The plurality of sets of dam structures 170 may be disposed so as to be spaced apart from each other by a desired (and/or alternatively predetermined) distance in the first horizontal direction X or the second horizontal direction Y. The plurality of sets of dam structures 170 may be disposed side by side with each other.

Referring to FIG. 2, the trench TR may extend so as to conform to the side surfaces of the main chip region MR. In some example embodiments, on a plane, the trench TR may have a rectangular frame shape that continuously extends along the perimeter of the main chip region MR. Referring to FIG. 3, each of trenches TR may extend so as to conform to one of the side surfaces of the main chip region MR. In some example embodiments, on a plane, a trench TR may have an elongated shape continuously extending along one side surface of the main chip region MR. The number of trenches TR may be two or more. Each of the plurality of trenches TR may extend so as to conform to a neighboring trench TR. The plurality of trenches TR may be disposed so as to be spaced apart from each other by a desired (and/or alternatively predetermined) distance in the first horizontal direction X or the second horizontal direction Y. The plurality of trenches TR may be disposed side by side with each other.

The numbers, shapes, and arrangements of guide ring structures 160, dam structures 170, and trenches TR are not limited to the above-described example embodiments, and in consideration of the characteristics of a product, crack propagation paths, wiring paths in the semiconductor chip 100, the material properties of each layer, the structural stability of the semiconductor chip 100, and so on, various numbers of guide ring structures 160, dam structures 170, and trenches TR having various shapes and arranged in various forms may be included in the scope of the present disclosure. For example, one trench TR may include a plurality of sub trenches TR which extends discontinuously from each other.

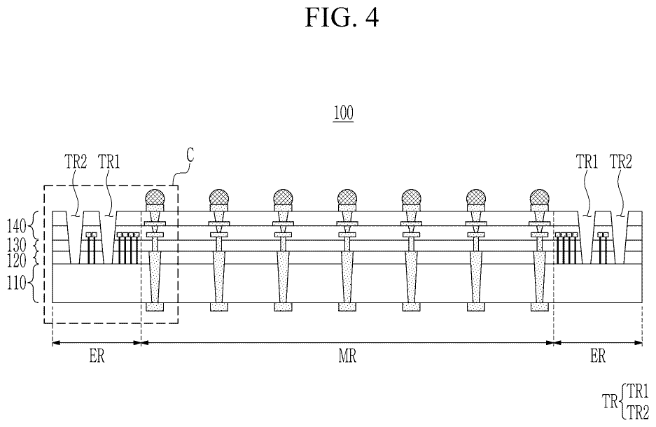

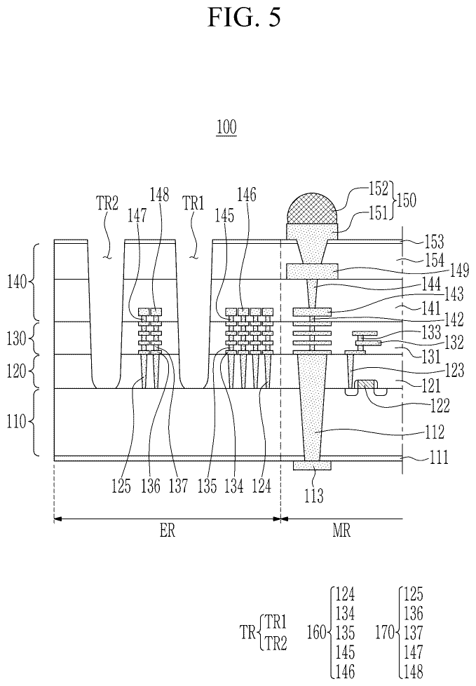

FIG. 4 is a cross-sectional view illustrating the semiconductor chip 100 according to some example embodiments. FIG. 4 is a cross-sectional view of the semiconductor chip 100 of FIG. 2 and the semiconductor chip 100 of FIG. 3 taken along line B-B′. FIG. 5 is an enlarged cross-sectional view illustrating a region C of FIG. 4.

Referring to FIGS. 4 and 5, the semiconductor chip 100 may include a chip base 110, a first passivation layer 111, a device layer 120, a wiring layer 130, an upper insulating stack 140, and a second passivation layer 153.

The chip base 110 may include an active surface (front side) and a back surface which is the opposite side to the active surface. The chip base 110 may be a die formed from a wafer. In some example embodiments, the chip base 110 may comprise silicon or other semiconductor materials. The chip base 110 may include a main chip region MR and an edge region ER. Through-silicon vias (TSVs) 112 may extend so as to pass through the chip base 110. The through-silicon vias (TSVs) 112 may be disposed between bonding pads 113 and first wiring lines 132 of the wiring layer 130. The through-silicon vias (TSVs) 112 may electrically connect the first wiring lines 132 of the wiring layer 130 to the bonding pads 113. In some example embodiments, the through-silicon vias (TSVs) 112 may comprise at least one of tungsten, aluminum, copper, and alloys thereof. The bonding pads 113 may be electrically connected to the through-silicon vias (TSVs) 112. In some example embodiments, the bonding pads 113 may comprise at least one of copper, aluminum, tungsten, nickel, gold, tin, titanium, and alloys thereof. However, example embodiments are not limited thereto.

The first passivation layer 111 may be disposed below the back surface of the chip base 110. In some example embodiments, the first passivation layer 111 may comprise at least one of silicon oxides, silicon nitrides, and SiCN. However, example embodiments are not limited thereto. The first passivation layer 111 may be disposed on the main chip region MR and the edge region ER and cover the back surface of the chip base 110. The through-silicon vias (TSVs) 112 may extend so as to pass through the first passivation layer 111.

The device layer 120 may be disposed on the active surface of the chip base 110. The device layer 120 may be disposed on the main chip region MR and the edge region ER, and may include an interlayer dielectric layer 121 which covers the chip base 110. In some example embodiments, the interlayer dielectric layer 121 may comprise at least one of silicon oxides, silicon nitrides, and silicon oxynitrides. The through-silicon vias (TSVs) 112 may extend so as to pass through the device layer 120.

In the main chip region MR, the device layer 120 may include integrated circuit structures 122 and contact plugs 123. The integrated circuit structures 122 and the contact plugs 123 may be surrounded by the interlayer dielectric layer 121. In some example embodiments, the integrated circuit structures 122 may include at least one of active devices and passive devices. In some example embodiments, the integrated circuit structures 122 may include a gate structure, a source region, and a drain region. In some example embodiments, the integrated circuit structures 122 may include at least one of transistors, diodes, capacitors, inductors, and resistors. The contact plugs 123 may be disposed between the integrated circuit structures 122 and the first wiring lines 132 of the wiring layer 130. The contact plugs 123 may electrically connect the first wiring lines 132 of the wiring layer 130 to the integrated circuit structures 122. In some example embodiments, the contact plugs 123 may comprise at least one of copper, aluminum, tungsten, nickel, gold, tin, titanium, and alloys thereof. However, example embodiments are not limited thereto.

In the edge region ER, the device layer 120 may include first patterns 124 of the guide ring structure 160 and first patterns 125 of the dam structure 170. The first patterns 124 of the guide ring structure 160 and the first patterns 125 of the dam structure 170 may be surrounded by the interlayer dielectric layer 121. The first patterns 124 of the guide ring structure 160 and the first patterns 125 of the dam structure 170 may be electrically disconnected from other components. In some example embodiments, each of the first patterns 124 of the guide ring structure 160 and the first patterns 125 of the dam structure 170 may comprise at least one of copper, aluminum, tungsten, nickel, gold, tin, titanium, and alloys thereof. However, example embodiments are not limited thereto.

The wiring layer 130 may be disposed on the device layer 120. The wiring layer 130 may be disposed on the main chip region MR and the edge region ER, and may include a first inter-metal dielectric layer 131 which covers the device layer 120. The first inter-metal dielectric layer 131 may comprise a low-dielectric constant (low-k) material having a dielectric constant smaller than the dielectric constant of silicon oxide. In some example embodiments, the first inter-metal dielectric layer 131 may comprise at least one of SiOCH and SiCN. However, example embodiments are not limited thereto.

In the main chip region MR, the wiring layer 130 may include the first wiring lines 132 and first wiring vias 133. The first wiring lines 132 and the first wiring vias 133 may be surrounded by the first inter-metal dielectric layer 131. The first wiring lines 132 and the first wiring vias 133 may be sequentially disposed between the contact plugs 123 of the device layer 120 and second wiring vias 142 of the upper insulating stack 140, or between the through-silicon vias (TSVs) 112 and the second wiring vias 142 of the upper insulating stack 140. The first wiring lines 132 and the first wiring vias 133 may electrically connect the second wiring vias 142 of the upper insulating stack 140 to the contact plugs 123 of the device layer 120, or may electrically connect the second wiring vias 142 of the upper insulating stack 140 to the through-silicon vias (TSVs) 112. In some example embodiments, each of the first wiring lines 132 and the first wiring vias 133 may comprise at least one of copper, aluminum, tungsten, nickel, gold, tin, titanium, and alloys thereof. However, example embodiments are not limited thereto.

In the edge region ER, the wiring layer 130 may include second patterns 134 and third patterns 135 of the guide ring structure 160 and second patterns 136 and third patterns 137 of the dam structure 170. The second patterns 134 and third patterns 135 of the guide ring structure 160 and the second patterns 136 and third patterns 137 of the dam structure 170 may be surrounded by the first inter-metal dielectric layer 131. The second patterns 134 and third patterns 135 of the guide ring structure 160 and the second patterns 136 and third patterns 137 of the dam structure 170 may be electrically disconnected from other components. In some example embodiments, each of the second patterns 134 and third patterns 135 of the guide ring structure 160 and the second patterns 136 and third patterns 137 of the dam structure 170 may comprise at least one of copper, aluminum, tungsten, nickel, gold, tin, titanium, and alloys thereof. However, example embodiments are not limited thereto.

The upper insulating stack 140 may be disposed on the wiring layer 130. The upper insulating stack 140 may be disposed on the main chip region MR and the edge region ER, and may include a first upper inter-metal dielectric layer 141 that covers the wiring layer 130, and a second upper inter-metal dielectric layer 154 that covers the first upper inter-metal dielectric layer 141. In some example embodiments, each of the first upper inter-metal dielectric layer 141 and the second upper inter-metal dielectric layer 154 may comprise one of tetraethyl orthosilicate (TEOS), SiN, SiO₂, SiOC, SiON, and SiCN. However, example embodiments are not limited thereto.

In the main chip region MR, the upper insulating stack 140 may include the second wiring vias 142, second wiring lines 143, third wiring vias 144, and a pad 149. The second wiring vias 142, the second wiring lines 143, and the third wiring vias 144 may be surrounded by the first upper inter-metal dielectric layer 141. The pad 149 may be surrounded by the second upper inter-metal dielectric layer 154. The second wiring vias 142, the second wiring lines 143, the third wiring vias 144, and the pad 149 may be sequentially disposed between the first wiring lines 132 of the wiring layer 130 and a bump structure 150. The second wiring vias 142, the second wiring lines 143, the third wiring vias 144, and the pad 149 may electrically connect the bump structure 150 to the first wiring lines 132 of the wiring layer 130. In some example embodiments, each of the second wiring vias 142, the second wiring lines 143, the third wiring vias 144, and the pad 149 may comprise at least one of copper, aluminum, tungsten, nickel, gold, tin, titanium, and alloys thereof. However, example embodiments are not limited thereto.

In the edge region ER, the upper insulating stack 140 may include fourth patterns 145 and fifth patterns 146 of the guide ring structure 160 and fourth patterns 147 and fifth patterns 148 of the dam structure 170. The fourth patterns 145 and fifth patterns 146 of the guide ring structure 160 and the fourth patterns 147 and fifth patterns 148 of the dam structure 170 may be surrounded by the first upper inter-metal dielectric layer 141. The fourth patterns 145 and fifth patterns 146 of the guide ring structure 160 and the fourth patterns 147 and fifth patterns 148 of the dam structure 170 may be electrically disconnected from other components. In some example embodiments, each of the fourth patterns 145 and fifth patterns 146 of the guide ring structure 160 and the fourth patterns 147 and fifth patterns 148 of the dam structure 170 may comprise at least one of copper, aluminum, tungsten, nickel, gold, tin, titanium, and alloys thereof. However, example embodiments are not limited thereto.

The second passivation layer 153 may be disposed on the upper insulating stack 140. In some example embodiments, the second passivation layer 153 may comprise at least one of silicon oxides, silicon nitrides, and SiCN. However, example embodiments are not limited thereto. The second passivation layer 153 may be disposed on the main chip region MR and the edge region ER, and cover the upper insulating stack 140.

The bump structure 150 may include a bump 151 and solder 152. The bump 151 may be in contact with the second upper inter-metal dielectric layer 154 and the second passivation layer 153. The bump 151 may pass through the second upper inter-metal dielectric layer 154 and be in contact with the pad 149. The bump 151 may pass through the second passivation layer 153, be exposed to the outside, and be in contact with the solder 152. The bump 151 may electrically connect the solder 152 to the pad 149. In some example embodiments, the bump 151 may comprise at least one of copper, aluminum, tungsten, nickel, gold, tin, titanium, and alloys thereof. However, example embodiments are not limited thereto. The solder 152 may be bonded to the upper surface of the bump 151. In some example embodiments, the solder 152 may comprise at least one of tin, silver, lead, nickel, copper, and alloys thereof. However, example embodiments are not limited thereto.

One or more guide ring structures 160 may be disposed in the edge region ER. A guide ring structure 160 may be formed over the device layer 120, the wiring layer 130, and the upper insulating stack 140. The guide ring structure 160 may include the first patterns 124, the second patterns 134, the third patterns 135, the fourth patterns 145, and the fifth patterns 146. Each of the first patterns 124, the second patterns 134, the third patterns 135, the fourth patterns 145, and the fifth patterns 146 may be formed together when each of the contact plugs 123, the first wiring lines 132, the first wiring vias 133, the second wiring vias 142, and the second wiring lines 143 in the same layer as that of the corresponding pattern is formed, and may have a structure similar to that of each of them.

One or more dam structures 170 may be disposed in the edge region ER. A dam structure 170 may be formed over the device layer 120, the wiring layer 130, and the upper insulating stack 140. The dam structure 170 may include the first patterns 125, the second patterns 136, the third patterns 137, the fourth patterns 147, and the fifth patterns 148. Each of the first patterns 125, the second patterns 136, the third patterns 137, the fourth patterns 147, and the fifth patterns 148 may be formed together when each of the contact plugs 123, the first wiring lines 132, the first wiring vias 133, the second wiring vias 142, and the second wiring lines 143 in the same layer as that of the corresponding pattern is formed, and may have a structure similar to that of each of them.

One or more trenches TR may be disposed in the edge region ER. One or more trenches TR may be disposed alternately with one or more guide ring structures 160 and one or more dam structures 170. A trench TR may have a cross-sectional shape recessed from the upper insulating stack 140 up to the device layer 120 via the wiring layer 130. The trench TR may pass through the second passivation layer 153, the upper insulating stack 140, the wiring layer 130, and the device layer 120. In some example embodiments, the trench TR may be recessed up to the lowermost surface of the device layer 120, and the chip base 110 may be exposed to the outside by the trench TR. In some example embodiments, the trench TR may be recessed up to the middle height of the device layer 120. The trench TR may have an empty space without being filled with a desired (and/or alternatively predetermined) material, and the inner surfaces of the trench TR may be exposed to the outside of the semiconductor chip 100. In some example embodiments, the trench TR may have a cross-sectional shape narrowing as it goes from the opening of the trench TR toward the bottom surface of the trench TR. In some example embodiments, the bottom surface of the trench TR may have a rounded shape.

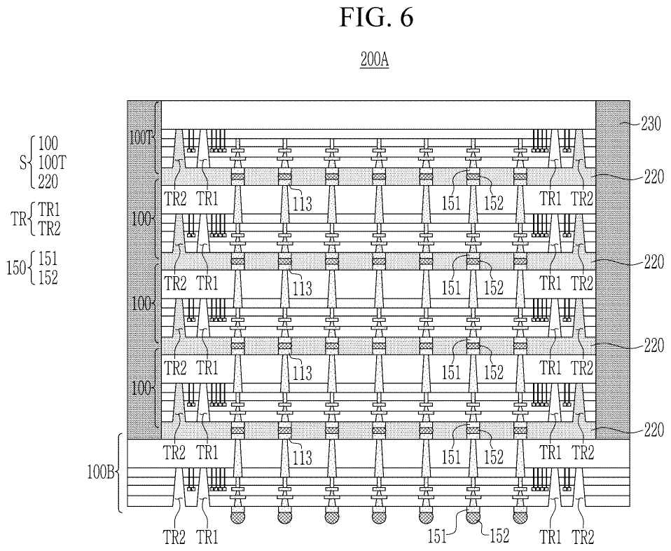

FIG. 6 is a cross-sectional view illustrating a semiconductor package 200A according to some example embodiments.

Referring to FIG. 6, the semiconductor package 200A may be a high bandwidth memory (HBM). The semiconductor package 200A may include a base die (buffer die) 100B, a semiconductor stack S including semiconductor chips 100 and 100T and underfill members 220, and a molding material 230.

The base die 100B may be disposed at the bottom in the high bandwidth memory (HBM). The base die 100B may have a structure similar to that of the semiconductor chip 100 described with reference to FIGS. 4 and 5. The base die 100B may include one or more trenches TR. In a high bandwidth memory (HBM) as a single product, the trench TR in the base die 100B may have an empty space without being filled with a material, and the inner surfaces of the trench TR may be exposed to the outside of the base die 100B. In a high bandwidth memory (HBM) disposed inside a semiconductor package, the trench TR in the base die 100B may be fully filled with an underfill member, or may include a void which is defined by the inner surfaces of the trench TR and the underfill member. In respect to the trench TR in the base die 100B, the following description of the trench TR in the semiconductor chip 100 may be equally applied.

The semiconductor stack S may be disposed on the base die 100B. The semiconductor stack S may include the semiconductor chips 100, bump structures 150, and the underfill members 220. The underfill members 220 and the semiconductor chips 100 may be sequentially and alternately stacked in the vertical direction on the base die 100B. Each of the bump structures 150 and the underfill members 220 may be disposed between the base die 100B and a semiconductor chip 100 neighboring the base die 100B, or between neighboring semiconductor chips 100 of the semiconductor chips 100. In some example embodiments, the bump structures 150 may include a micro bump.

The underfill member 220 between the base die 100B and the semiconductor chip 100 neighboring the base die 100B may surround and insulate the bonding pads 113 of the base die 100B and the bump structures 150. An underfill member 220 between neighboring semiconductor chips 100 may surround and insulate the bonding pads 113 of the semiconductor chip 100 and the bump structures 150 positioned below the underfill member. In some example embodiments, the underfill members 220 may include a non-conductive film (NCF).

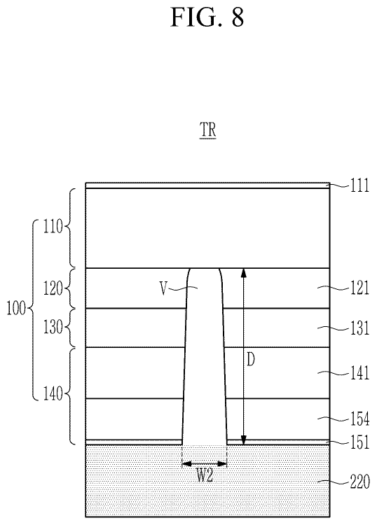

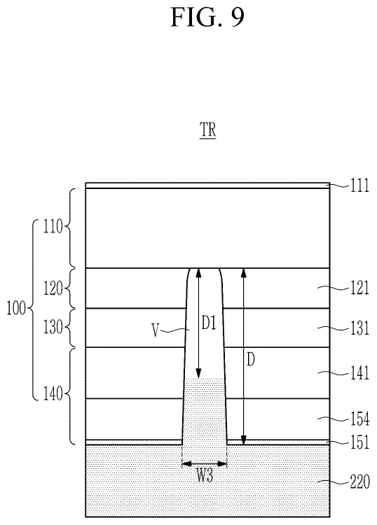

Each of the semiconductor chips 100 may include one or more trenches TR. A trench TR in a semiconductor chip 100 may be fully filled with an underfill member 220, or may include a void V (see FIGS. 8 and 9) which is defined by the inner surfaces of the trench TR and an underfill member 220. In the semiconductor stack S, the semiconductor chip 100T positioned at the top may not include through-silicon vias (TSVs) 112, and its upper surface may be exposed from the molding material 230 to the outside.

The molding material 230 may be disposed on the base die 100B, and cover the semiconductor stack S. The molding material 230 may serve to protect and insulate the semiconductor stack S. In some example embodiments, the molding material 230 may comprise an epoxy molding compound (EMC).

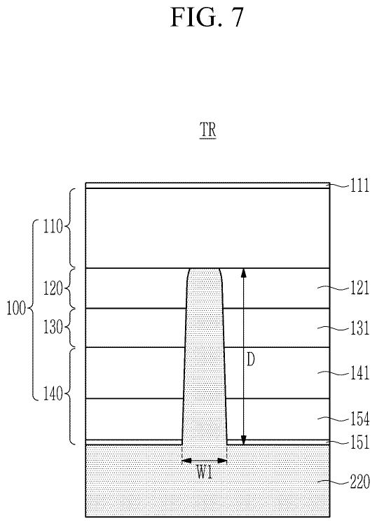

Each of FIGS. 7, 8, and 9 is a cross-sectional view illustrating a trench TR according to some example embodiments.

Referring to FIG. 7, a trench TR in a semiconductor chip 100 may be fully filled with an underfill member 220. In order for the underfill member 220 to fully fill the trench TR, the underfill member 220 should be able to pass through the opening of the trench TR while a thermal compression (TC) process is performed on the underfill member 220. In some example embodiments, the opening of the trench TR may have a width W1 ranging from about 5 μm to about 15 μm. In some example embodiments, the trench TR may have a depth D ranging from about 5 μm to about 13 μm. In some example embodiments, the trench TR may have an aspect ratio ranging from about 5:13 to about 3:1.

Referring to FIGS. 8 and 9, a trench TR in a semiconductor chip 100 may include a void V which is defined by the inner surfaces of the trench TR and an underfill member 220. The void V may have a depth D1 in the vertical direction and occupy at least a portion of the inner space of the trench TR. In order to form the void V which is defined by the inner surfaces of the trench TR and the underfill member 220, it should be difficult for the underfill member 220 to pass through the opening of the trench TR while a thermal compression (TC) process is performed on the underfill member 220. In some example embodiments, the opening of the trench TR may have a width W2 or W3 ranging from about 1 μm to about 13 μm. In some example embodiments, the trench TR may have a depth D ranging from about 5 μm to about 13 μm. In some example embodiments, the trench TR may have an aspect ratio ranging from about 1:13 to about 13:5.

The number of trenches TR in a semiconductor chip 100 may be two or more. In some example embodiments, a semiconductor chip 100 may include only trenches TR according to some example embodiments as represented by FIG. 7. In some example embodiments, a semiconductor chip 100 may include only trenches TR according to some example embodiments as represented by FIG. 8. In some example embodiments, a semiconductor chip 100 may include only trenches TR according to some example embodiments as represented by FIG. 9. In some example embodiments, a semiconductor chip 100 may include various combinations of trenches TR described with reference to FIGS. 7, 8, and 9.

In a conventional trench, its inner space may be filled with a gap filling material comprising a material such as silicon oxide, silicon nitride, or silicon oxynitride. However, the material such as silicon oxide, silicon nitride, or silicon oxynitride has a relatively large modulus value and has a hard property, and thus, is fragile. Accordingly, it is not uncommon for cracks to propagate to the main chip region MR while damaging the gap filling material in the trench.

According to the present disclosure, the inner space of a trench TR in a semiconductor chip 100 may be filled with a non-conductive film (NCF) or a molded underfill (MUF) having a relatively low modulus value, or has an empty space. Therefore, it is possible to efficiently reduce and/or prevent cracks from propagating toward the main chip region MR. Further, in consideration of the characteristics of a semiconductor chip according to a generational transition in semiconductor products, an optimal trench (TR) structure capable of limiting and/or preventing propagation of cracks can be designed. For example, inside a semiconductor chip 100, a plurality of trenches TR filled with non-conductive films (NCFs) or MUFs or a plurality of trenches TR with voids V may be disposed, or trenches TR filled with non-conductive films (NCFs) or MUFs and trenches TR with voids V may be alternately disposed.

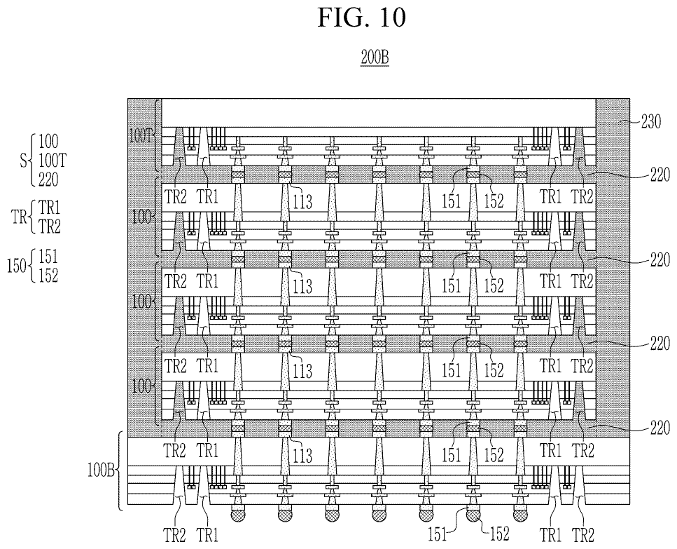

FIG. 10 is a cross-sectional view illustrating a semiconductor package 200B according to some example embodiments.

Referring to FIG. 10, the semiconductor package 200B may be a high bandwidth memory (HBM). The semiconductor package 200B may include a base die (buffer die) 100B, a semiconductor stack S including semiconductor chips 100 and 100T and underfill members 220, and a molding material 230. In some example embodiments, the underfill members 220 may include a molded underfill (MUF). The MUF may comprise the same material as that of the molding material 230, and may be formed integrally with the molding material 230 in the same process. There is no boundary between the underfill members 220 and the molding material 230, but it is shown by a dotted line in FIG. 10 for convenience. In some example embodiments, the underfill members 220 may be an epoxy molding compound (EMC).

In respect to the semiconductor package 200B of FIG. 10 other than the above-mentioned contents, the contents about the semiconductor package 200A described with reference to FIGS. 6, 7, 8, and 9 may be applied.

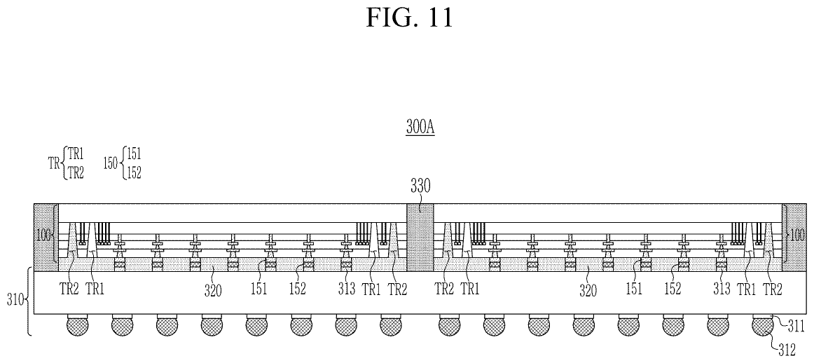

FIG. 11 is a cross-sectional view illustrating a semiconductor package 300A according to some example embodiments.

Referring to FIG. 11, the semiconductor package 300A may include a base structure 310, semiconductor chips 100, bump structures 150, underfill members 320, and a molding material 330.

The base structure 310 may be disposed at the bottom in the semiconductor package 300A. In some example embodiments, the base structure 310 may include an interposer, a redistribution structure, a glass substrate, a printed circuit board, or an additional semiconductor chip. However, example embodiments are not limited thereto. On the lower surface of the base structure 310, connection pads 311 and connection member 312 may be disposed, and the base structure 310 may be connected to an external device.

The semiconductor chips 100 may be disposed on the base structure 310. The semiconductor chips 100 may be disposed side by side with each other. Each of the semiconductor chips 100 may include one or more trenches TR. A trench TR in a semiconductor chip 100 may be fully filled with an underfill member 220, or may include a void V (see FIGS. 8 and 9) which is defined by the inner surfaces of the trench TR and an underfill member 220. The semiconductor chips 100 may not include through-silicon vias (TSVs) 112, and their upper surfaces may be exposed from the molding material 330 to the outside.

Each of the bump structures 150 and the underfill members 320 may be disposed between the base structure 310 and each of the semiconductor chips 100. In some example embodiments, the bump structures 150 may include a micro bump. Each of the underfill members 320 may surround and insulate bonding pads 313 of the base structure 310 and the bump structures 150. In some example embodiments, the underfill members 320 may include a non-conductive film (NCF).

The molding material 330 may be disposed on the base structure 310 and cover the semiconductor chips 100. The molding material 330 may serve to protect and insulate the semiconductor chips 100. In some example embodiments, the molding material 330 may comprise an epoxy molding compound (EMC).

In respect to a trench TR of the semiconductor chips 100 of FIG. 11 other than the above-mentioned contents, the contents about a trench TR of the semiconductor chips 100 described with reference to FIGS. 7, 8, and 9 may be applied.

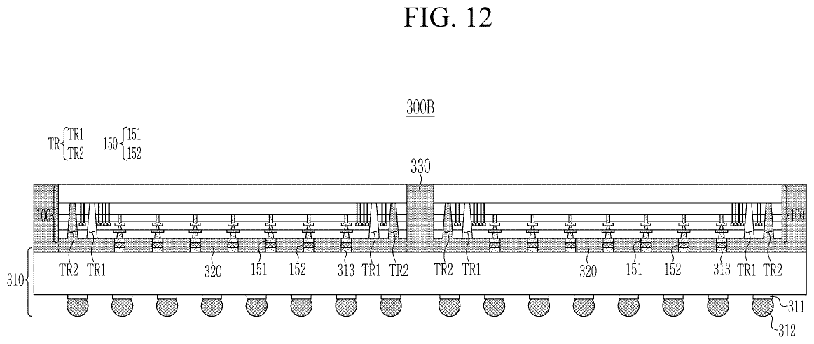

FIG. 12 is a cross-sectional view illustrating a semiconductor package 300B according to some example embodiments.

Referring to FIG. 12, the semiconductor package 300B may include a base structure 310, semiconductor chips 100, bump structures 150, underfill members 320, and a molding material 330. In some example embodiments, the underfill members 320 may include a molded underfill (MUF). However, example embodiments are not limited thereto. The MUF may comprise the same material as that of the molding material 330, and may be formed integrally with the molding material 330 in the same process. There is no boundary between the underfill members 320 and the molding material 330, but it is shown by a dotted line in FIG. 12 for convenience. In some example embodiments, the underfill members 320 may be an epoxy molding compound (EMC). However, example embodiments are not limited thereto.

In respect to the semiconductor package 300B of FIG. 12 other than the above-mentioned contents, the contents about the semiconductor package 300A described with reference to FIG. 11 may be applied.

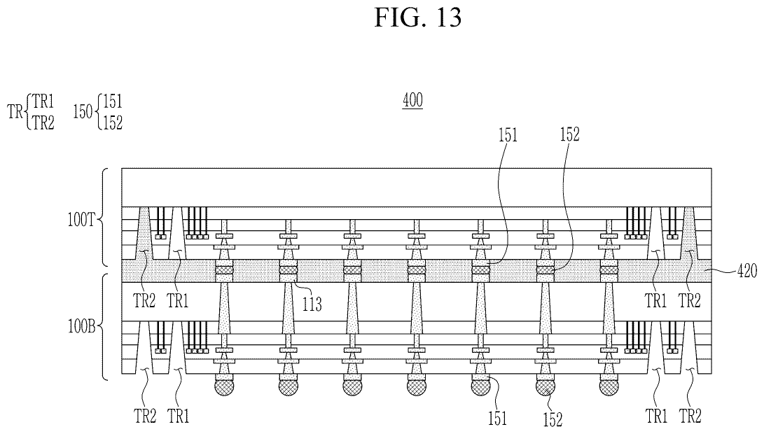

FIG. 13 is a cross-sectional view illustrating a semiconductor package 400 according to some example embodiments.

Referring to FIG. 13, the semiconductor package 400 may include a three-dimensional integrated circuit structure. The semiconductor package 400 may include a lower semiconductor chip 100L, an upper semiconductor chip 100T, bump structures 150, and an underfill member 320.

The lower semiconductor chip 100L may be disposed below the upper semiconductor chip 100T. The lower semiconductor chip 100L may include one or more trenches TR. In a three-dimensional integrated circuit structure as a single product, a trench TR of the lower semiconductor chip 100L may not be filled with a desired (and/or alternatively predetermined) material, and may have an empty space, and the inner surfaces of the trench TR may be exposed to the outside of the lower semiconductor chip 100L. In a three-dimensional integrated circuit structure disposed inside another semiconductor package, a trench TR in the lower semiconductor chip 100L may be fully filled with an underfill member, or may include a void V (see FIGS. 8 and 9) which is defined by the inner surfaces of the trench TR and the underfill member.

The upper semiconductor chip 100T may be disposed on the lower semiconductor chip 100L. The upper semiconductor chip 100T may include one or more trenches TR. A trench TR in the upper semiconductor chip 100T may be fully filled with an underfill member 420, or may include a void V (see FIGS. 8 and 9) which is defined by the inner surfaces of the trench TR and the underfill member 420. The upper semiconductor chip 100T may not include through-silicon vias (TSVs) 112.

The bump structures 150 and the underfill member 420 may be disposed between the lower semiconductor chip 100L and the upper semiconductor chip 100T. In some example embodiments, the bump structures 150 may include a micro bump. The underfill member 420 may surround and insulate the bonding pads 113 of the lower semiconductor chip 100L and the bump structures 150. In some example embodiments, the underfill member 420 may include a non-conductive film (NCF).

In respect to a trench TR of the lower semiconductor chip 100L and a trench TR of the upper semiconductor chip 100T of FIG. 13 other than the above-mentioned contents, the contents about a trench TR of the semiconductor chips 100 described with reference to FIGS. 7, 8, and 9 may be applied.

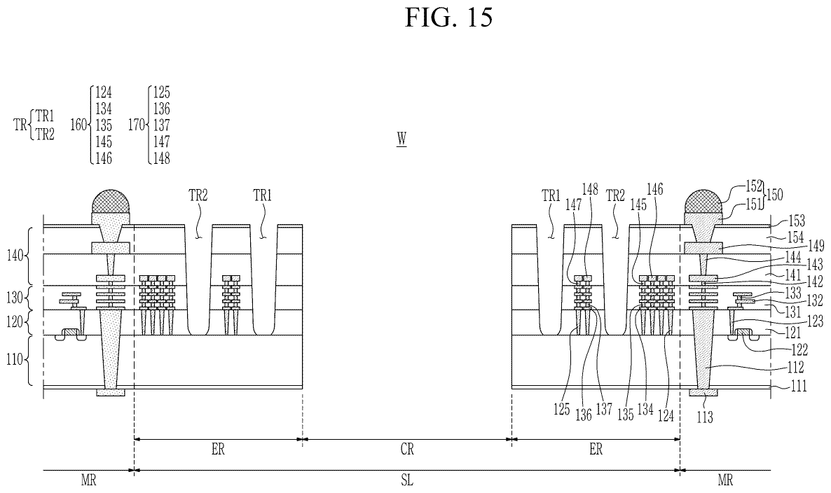

FIGS. 14 and 15 are cross-sectional views illustrating a method of forming the semiconductor chip 100 of FIG. 4 from the semiconductor wafer W of FIG. 1.

FIG. 14 is a cross-sectional view of the semiconductor wafer W of FIG. 1 taken along line A-A′.

Referring to FIG. 14, the semiconductor wafer W may include main chip regions MR and a scribe lane SL. The scribe lane SL may be defined as a region between the main chip regions MR. The scribe lane SL may include a cutting region CR and an edge region ER.

FIG. 15 is a cross-sectional view illustrating a step of singulation of semiconductor chips 100 from the semiconductor wafer W.

Referring to FIG. 15, the semiconductor wafer W may be divided into individual semiconductor chips 100 by performing the singulation process. In some example embodiments, the singulation process may be performed by a blade, a laser, or plasma etching. However, example embodiments are not limited thereto. After the singulation process, a semiconductor chip 100 may include a main chip region MR and an edge region ER.

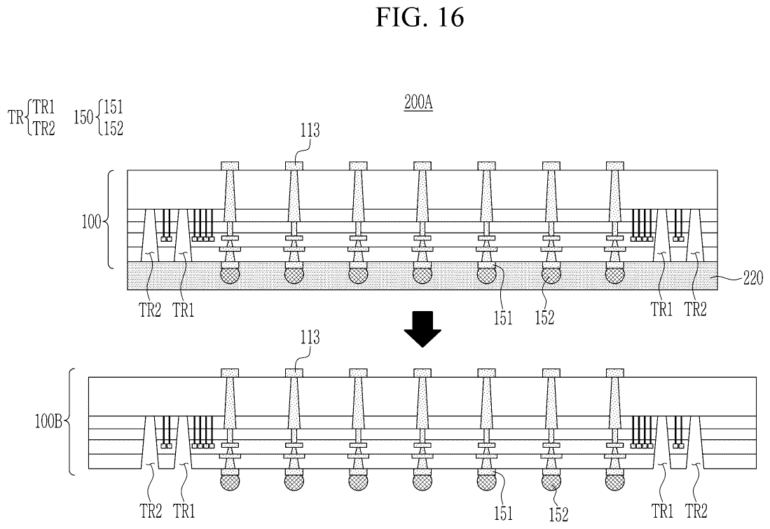

FIGS. 16 to 19 are cross-sectional views illustrating a method of manufacturing the semiconductor package 200A according to some example embodiments as represented by FIG. 6.

FIG. 16 is a cross-sectional view illustrating a step of aligning a semiconductor chip 100 on the base die 100B.

Referring to FIG. 16, a semiconductor chip 100 may be aligned on the base die 100B. An underfill member 220 may be attached to the lower surface of the semiconductor chip 100, and the bump structures 150 may be surrounded by the underfill member 220.

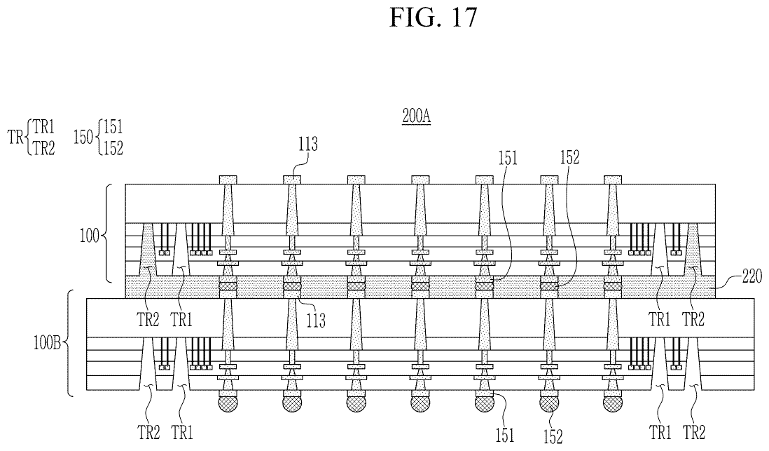

FIG. 17 is a cross-sectional view illustrating a step of bonding the semiconductor chip 100 on the base die 100B.

Referring to FIG. 17, the semiconductor chip 100 may be bonded on the base die 100B. The semiconductor chip 100 may be bonded to the upper surface of the base die 100B by a thermal compression (TC) process. However, example embodiments are not limited thereto. By the thermal compression (TC) process, each of the bump structures 150 may be bonded to corresponding bonding pad of the bonding pads 113, respectively.

The underfill member 220 may be attached between the base die 100B and the semiconductor chip 100, and protect and insulate the bump structures 150 and the bonding pads 113. The underfill member 220 is in a gel state before the thermal compression (TC) process is performed, and transitions from the gel state to a liquid state by heat which is applied while the thermal compression (TC) process is performed, and finally becomes a cured state. While the thermal compression (TC) process is performed, the underfill member 220 in the liquid state may flow into the inner space of a trench TR according to the size of the opening of the trench TR to fully fill the inside of the trench TR. Alternatively, the underfill member 220 in the liquid state may flow into the inner space of the trench TR according to the size of the opening of the trench TR and form a void V which occupies a portion of the inner space of the trench TR, or may not be able to flow into the inner space of the trench TR, and thus, form a void V which occupies the entire inner space of the trench TR. The underfill member 220 may become a cured state after the thermal compression (TC) process is completed.

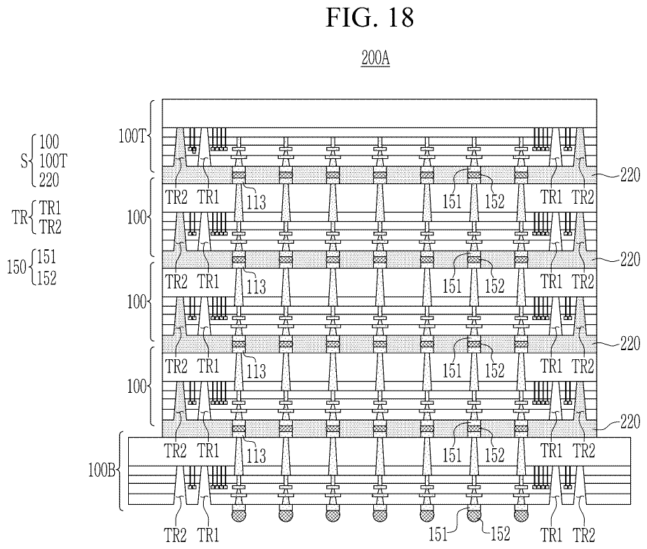

FIG. 18 is a cross-sectional view illustrating a step of stacking semiconductor chips 100.

Referring to FIG. 18, by repeatedly performing alignment of a semiconductor chip 100 and a thermal compression (TC) process, semiconductor chips 100 and underfill members 220 may be stacked such that the semiconductor chips 100 and the underfill members 220 alternate with each other. In FIG. 17, as described above, while a thermal compression (TC) process is performed, an underfill member 220 in the liquid state may flow into the inner space of a trench TR according to the size of the opening of the trench TR and fully fill the inside of the trench TR. Alternatively, the underfill member 220 in the liquid state may flow into the inner space of the trench TR according to the size of the opening of the trench TR and form a void V which occupies a portion of the inner space of the trench TR, or may not be able to flow into the inner space of the trench TR, and thus, form a void V which occupies the entire inner space of the trench TR. The underfill member 220 may become a cured state after the thermal compression (TC) process is completed.

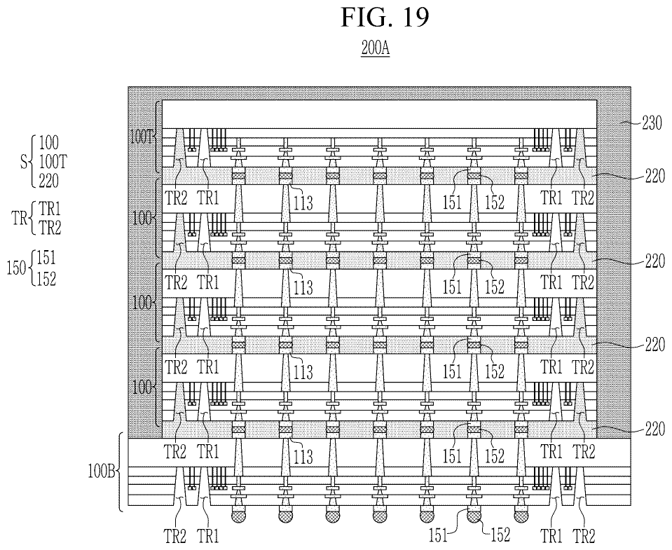

FIG. 19 is a cross-sectional view illustrating a step of encapsulating the semiconductor chips 100 and the underfill members 220 stacked on the base die 100B.

Referring to FIG. 19, the semiconductor chips 100 and the underfill members 220 stacked on the base die 100B may be encapsulated by the molding material 230. The process of performing encapsulating by the molding material 230 may include a compression molding or transfer molding process. Thereafter, the upper surface of the molding material 230 may be planarized by performing a chemical mechanical planarization (CMP) process. After the chemical mechanical planarization (CMP) process is performed, the upper surface of the semiconductor chip 100T may be exposed.

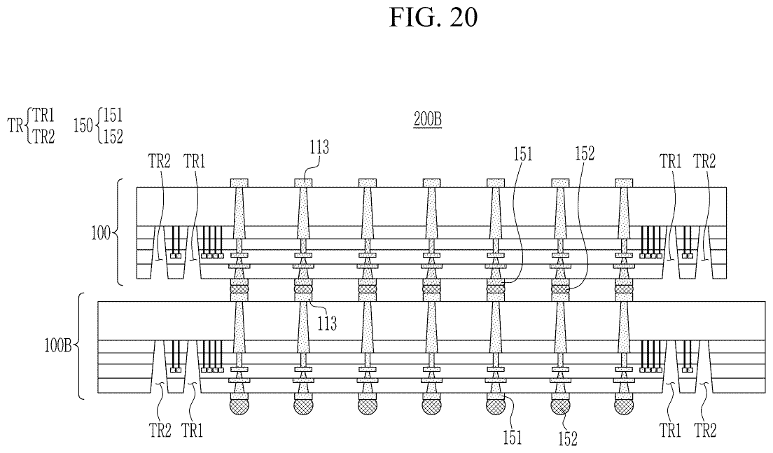

FIGS. 20 to 22 are cross-sectional views illustrating a method of manufacturing the semiconductor package 200B according to some example embodiments as represented by FIG. 10.

FIG. 20 is a cross-sectional view illustrating a step of mounting a semiconductor chip 100 on the base die 100B.

Referring to FIG. 20, a semiconductor chip 100 may be mounted on the base die 100B. In some example embodiments, a semiconductor chip 100 may be mounted on the base die 100B by performing a flip-chip bonding process.

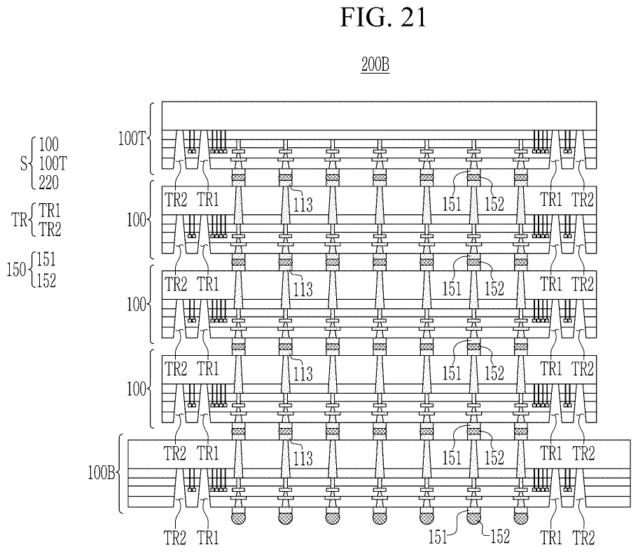

FIG. 21 is a cross-sectional view illustrating a step of stacking the semiconductor chips 100.

Referring to FIG. 21, the semiconductor chips 100 may be sequentially stacked from the bottom. In some example embodiments, the semiconductor chips 100 may be stacked by performing a flip-chip bonding process.

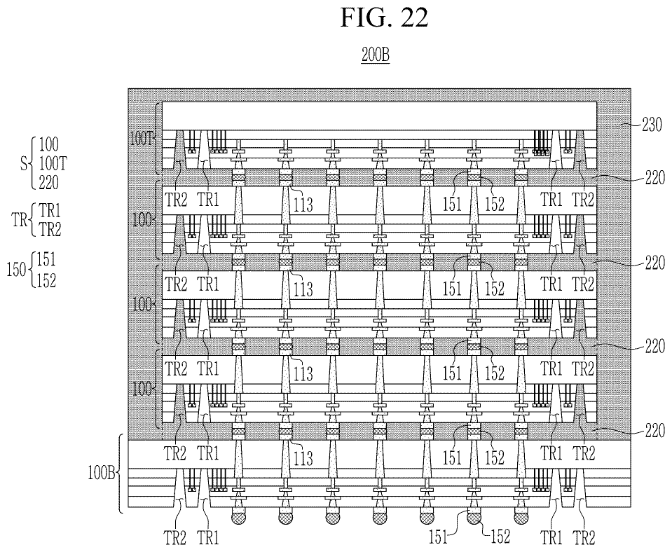

FIG. 22 is a cross-sectional view illustrating a step of encapsulating the semiconductor chips 100 stacked on the base die 100B.

Referring to FIG. 22, the semiconductor chips 100 stacked on the base die 100B may be encapsulated by the molding material 230. While the encapsulating process is performed, the molding material 230 may serve as an underfill member 220 simultaneously to fill between the base die 100B and the semiconductor chip 100 neighboring the base die 100B and between neighboring semiconductor chips 100. The underfill member 220 may be the same material as the molding material 230. The underfill member 220 in the liquid state may flow into the inner space of a trench TR according to the size of the opening of the trench TR to fully fill the inside of the trench TR. Alternatively, the underfill member 220 in the liquid state may flow into the inner space of the trench TR according to the size of the opening of the trench TR and form a void V which occupies a portion of the inner space of the trench TR, or may not be able to flow into the inner space of the trench TR, and thus, form a void V which occupies the entire inner space of the trench TR. The underfill member 220 and the molding material 230 may become a cured state after the encapsulating process is completed. As an example, the process of performing encapsulating by the molding material 230 may include a compression molding or transfer molding process. In some example embodiments, the molding material 230 may comprise an epoxy molding compound (EMC). However, example embodiments are not limited thereto.

Thereafter, the upper surface of the molding material 230 may be planarized by performing a chemical mechanical planarization (CMP) process. However, example embodiments are not limited thereto. After the chemical mechanical planarization (CMP) process is performed, the upper surface of the semiconductor chip 100T may be exposed.

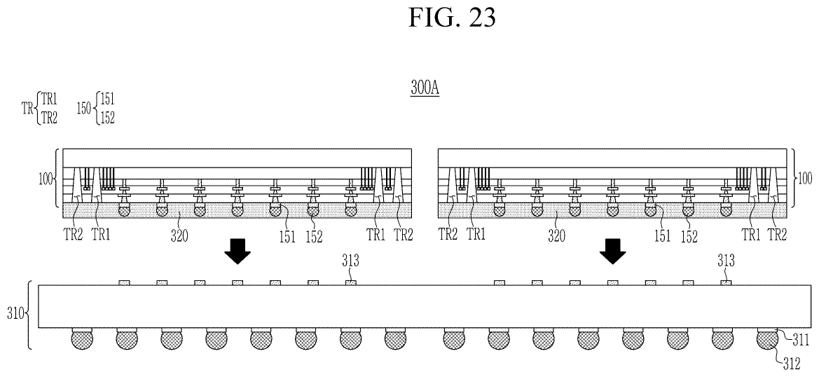

FIGS. 23 to 25 are cross-sectional views illustrating a method of manufacturing the semiconductor package 300A according to some example embodiments as represented by FIG. 11.

FIG. 23 is a cross-sectional view illustrating a step of aligning the semiconductor chips 100 on the base structure 310.

Referring to FIG. 23, the semiconductor chips 100 may be aligned on the base structure 310. The underfill member 320 may be attached to the lower surface of each of the semiconductor chips 100, and the bump structures 150 may be surrounded by the underfill member 320.

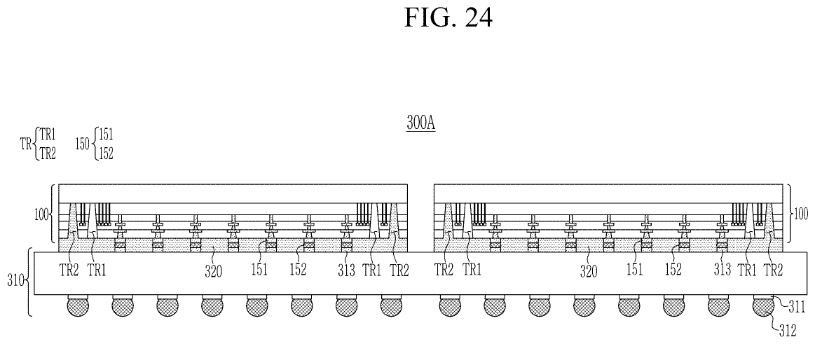

FIG. 24 is a cross-sectional view illustrating a step of bonding the semiconductor chips 100 to the upper surface of the base structure 310.

Referring to FIG. 24, the semiconductor chips 100 may be bonded to the upper surface of the base structure 310. The semiconductor chips 100 may be bonded to the base structure 310 by a thermal compression (TC) process. However, example embodiments are not limited thereto. By the thermal compression (TC) process, the bump structures 150 may be bonded to the bonding pads 313, respectively.

The underfill member 320 may be attached between the base structure 310 and a semiconductor chip 100, and protect and insulate the bump structures 150 and the bonding pads 313. The underfill member 320 is in a gel state before the thermal compression (TC) process is performed, and transitions from the gel state to a liquid state by heat which is applied while the thermal compression (TC) process is performed, and finally becomes a cured state. While the thermal compression (TC) process is performed, the underfill member 320 in the liquid state may flow into the inner space of a trench TR according to the size of the opening of the trench TR to fully fill the inside of the trench TR. Alternatively, the underfill member 320 in the liquid state may flow into the inner space of the trench TR according to the size of the opening of the trench TR and form a void V which occupies a portion of the inner space of the trench TR, or may not be able to flow into the inner space of the trench TR, and thus, form a void V which occupies the entire inner space of the trench TR. The underfill member 320 may become a cured state after the thermal compression (TC) process is completed.

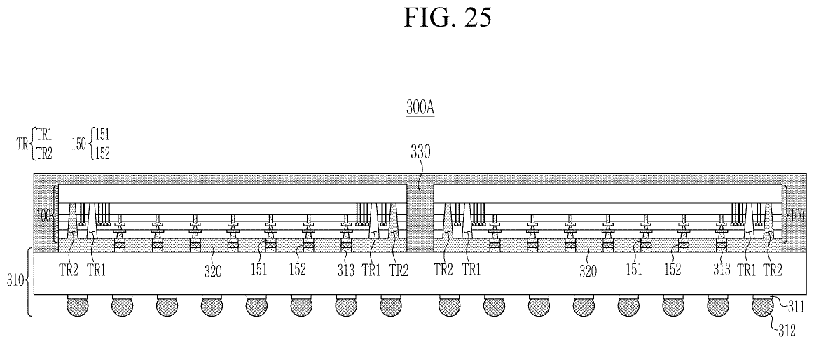

FIG. 25 is a cross-sectional view illustrating a step of encapsulating the semiconductor chips 100 and the underfill members 320 on the base structure 310.

Referring to FIG. 25, the semiconductor chips 100 and the underfill members 320 may be encapsulated on the base structure 310 by the molding material 330. The process of performing encapsulating by the molding material 330 may include a compression molding or transfer molding process. Thereafter, the upper surface of the molding material 330 may be planarized by performing a chemical mechanical planarization (CMP) process. After the chemical mechanical planarization (CMP) process is performed, the upper surface of each of the semiconductor chips 100 may be exposed.

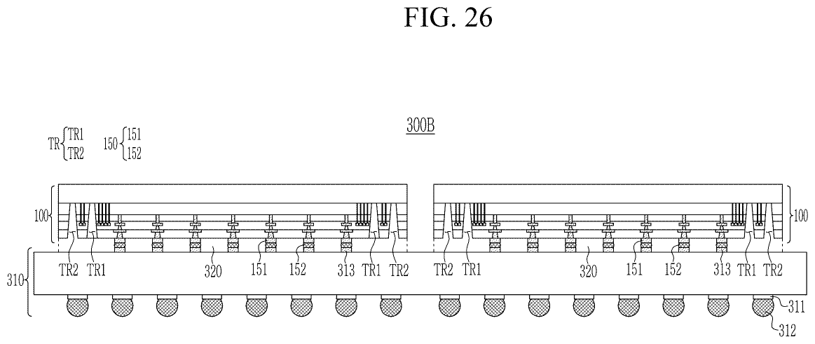

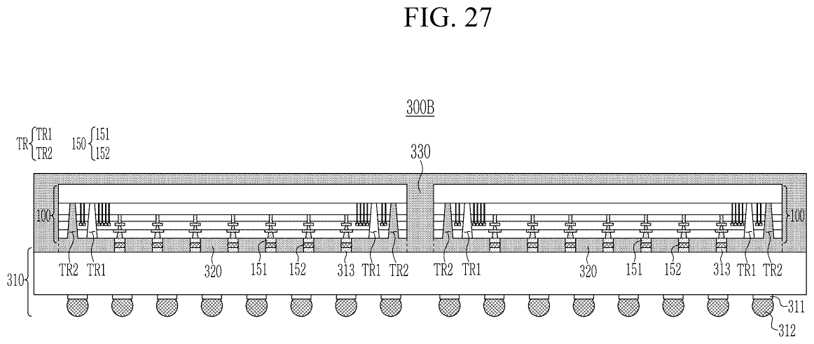

FIGS. 26 and 27 are cross-sectional views illustrating a method of manufacturing the semiconductor package 300B according to some example embodiments as represented by FIG. 12.

FIG. 26 is a cross-sectional view illustrating a step of mounting the semiconductor chips 100 on the base structure 310.

Referring to FIG. 26, the semiconductor chips 100 may be mounted on the base structure 310. In some example embodiments, the semiconductor chips 100 may be mounted on the base structure 310 by performing a flip-chip bonding process.

FIG. 27 is a cross-sectional view illustrating a step of encapsulating the semiconductor chips 100 on the base structure 310.

Referring to FIG. 27, the semiconductor chips 100 may be encapsulated on the base structure 310 by the molding material 330. While the encapsulating process is performed, the molding material 330 may serve as an underfill member 320 simultaneously to fill between the base structure 310 and the semiconductor chips 100. The underfill member 320 may be the same material as the molding material 330. The underfill member 320 in the liquid state may flow into the inner space of a trench TR according to the size of the opening of the trench TR to fully fill the inside of the trench TR. Alternatively, the underfill member 320 in the liquid state may flow into the inner space of the trench TR according to the size of the opening of the trench TR and form a void V which occupies a portion of the inner space of the trench TR, or may not be able to flow into the inner space of the trench TR, and thus, form a void V which occupies the entire inner space of the trench TR. The underfill member 320 and the molding material 330 may become a cured state after the encapsulating process is completed. As an example, the process of performing encapsulating by the molding material 330 may include a compression molding or transfer molding process. In some example embodiments, the molding material 330 may comprise an epoxy molding compound (EMC).

Thereafter, the upper surface of the molding material 330 may be planarized by performing a chemical mechanical planarization (CMP) process. However, example embodiments are not limited thereto. After the chemical mechanical planarization (CMP) process is performed, the upper surface of the semiconductor chip 100T may be exposed.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While this invention has been described in connection with what is presently considered to be practical example embodiments, it is to be understood that the invention is not limited to the disclosed example embodiments. On the contrary, it is intended to cover various modifications and equivalent arrangements included within the spirit and scope of the appended claims.

What is claimed is:

1. A semiconductor chip comprising:
a chip base including a main chip region and an edge region around the main chip region;
a device layer on the chip base;
a wiring layer on the device layer;
an upper insulating stack on the wiring layer; and
a trench on the edge region,
the trench recessed from the upper insulating stack to the device layer, and
an inner surface of the trench exposed to an outside of the semiconductor chip.

2. The semiconductor chip of claim 1, wherein
the chip base is exposed to the outside of the semiconductor chip by the trench.

3. The semiconductor chip of claim 1, wherein
in a planar view, the trench has a rectangular frame shape that extends along a perimeter of the main chip region.

4. The semiconductor chip of claim 1, wherein
the trench includes a plurality of trenches, and
in a planar view, each of the plurality of trenches extends conformally to a neighboring trench.

5. The semiconductor chip of claim 1, wherein
the trench has a depth ranging from 5 μm to 13 μm.

6. The semiconductor chip of claim 1, wherein
the trench has a cross-sectional shape narrowing from an opening of the trench toward a bottom surface of the trench.

7. A semiconductor package comprising:
a base structure;
an underfill member on the base structure; and
a semiconductor chip on the underfill member, the semiconductor chip including
a chip base including a main chip region and an edge region around the main chip region,
a device layer on the chip base,
a wiring layer on the device layer,
an upper insulating stack on the wiring layer, and
a first trench on the edge region,
the first trench recessed from the upper insulating stack to the device layer, and
an inner surface of the first trench is exposed to an outside of the semiconductor chip,
wherein the first trench is fully filled with the underfill member, or the first trench includes a void defined by the inner surface of the first trench and the underfill member.

8. The semiconductor package of claim 7, wherein
the base structure includes
an interposer,
a redistribution structure,
a glass substrate,
a printed circuit board, or
an additional semiconductor chip.

9. The semiconductor package of claim 7, wherein
the underfill member includes a non-conductive film (NCF).

10. The semiconductor package of claim 7, further comprising:
a molding material covering the underfill member and the semiconductor chip on the base structure,
wherein the underfill member includes a molded underfill (MUF).

11. The semiconductor package of claim 7, wherein
the semiconductor chip further includes a second trench next to the first trench on the edge region,
the second trench recessed from the upper insulating stack to the device layer,
an inner surface of the second trench exposed to the outside of the semiconductor chip, and
the second trench filled with the underfill member, or
the second trench including a void defined by the inner surface of the second trench and the underfill member.

12. The semiconductor package of claim 11, wherein
the first trench filled with the underfill member, and
the second trench includes the void defined by the inner surface of the second trench and the underfill member.

13. The semiconductor package of claim 12, wherein
an opening of the first trench has a width ranging from 5 μm to 15 μm.

14. The semiconductor package of claim 12, wherein
the first trench has an aspect ratio ranging from 5:13 to 3:1.

15. The semiconductor package of claim 12, wherein
an opening of the second trench has a width ranging from 1 μm to 13 μm.

16. The semiconductor package of claim 12, wherein
the second trench has an aspect ratio ranging from 1:13 to 13:5.

17. The semiconductor package of claim 7, wherein
the semiconductor chip further includes one or more dam structures next to the first trench on the edge region.

18. The semiconductor package of claim 7, wherein
the semiconductor chip further includes one or more guide ring structures next to the first trench on the edge region.

19. The semiconductor package of claim 7, wherein
the void occupies at least a portion of an inner space of the first trench.

20. A semiconductor package comprising:
a base die;
one or more underfill members and a plurality of semiconductor chips alternately stacked on the base die; and
a molding material covering the one or more underfill members and the plurality of semiconductor chips on the base die,
wherein each of the plurality of semiconductor chips includes
a chip base including a main chip region and an edge region around the main chip region,
a device layer on the chip base,
a wiring layer on the device layer,
an upper insulating stack on the wiring layer, and
a first trench on the edge region,
the first trench recessed from the upper insulating stack to the device layer,
an inner surface of the first trench exposed to an outside of each of the plurality of semiconductor chips, and
the first trench filled with an underfill member, or
the first trench includes a void defined by the inner surface of the first trench and an underfill member adjacent to the first trench.
